(19) United States
(12) Patent Application Publication
(10) Pub. No.: US 2026/0305258 A1
(43) Pub. Date: Oct. 1, 2026

(54) ADJUSTABLE CHUCK FOR WAFER BONDING

(71) Applicant: Tokyo Electron Limited, Tokyo (JP)

(72) Inventors: Adam GILDEA, Albany, NY (US); Christopher NETZBAND, Albany, NY (US)

(73) Assignee: Tokyo Electron Limited, Tokyo (JP)

(21) Appl. No.: 19/094,384

(22) Filed: Mar. 28, 2025

(51) Int. Cl. H10P 72/76; H10P 10/00; H10P 72/70; H10P 72/78

(52) U.S. Cl. CPC H10P 72/7624; H10P 10/128; H10P 72/74; H10P 72/7616; H10P 72/78; H10P 72/744

(57) ABSTRACT

Conformal semiconductor chucks are disclosed. The semiconductor chucks can include an inner portion comprising a first material, and having an opening to receive a striker. The semiconductor chucks can include an outer portion comprising a vacuum pad, wherein the outer portion is configured to move vertically, relative to the inner portion while coupled with a semiconductor wafer.

### TECHNICAL FIELD

This disclosure relates to semiconductor wafer handling devices. The semiconductor wafer handling devices can interface with semiconductor wafers during bonding or other operations.

### BACKGROUND

Fabrication of semiconductor devices can include wafer stacking and bonding, among other processing or handling operations which can impart stress or cause displacement of the wafers. Such stress or displacement, or variations along portions of a wafer, can impact alignment, performance, and yield in semiconductor devices.

### SUMMARY

In order to continue scaling down semiconductor devices, device structures can be designed to extend in their vertical direction, such as upwards from the substrate on which they are fabricated. Such designs can employ various stacked layers, such as any number of stacked wafers. The stacked wafers can be coupled with one another via van der Waals forces, electrostatic forces, or chemical bonds at a bonding interface. Bonding (e.g., adhesive) materials can mechanically couple wafers, or ohmic connections can be formed between wafers. Wafers can be disposed between wafer chucks (e.g., a top wafer chuck and a bottom wafer chuck) to impart thermal energy, pressure, maintain wafer flatness, or otherwise encourage wafer bonding. The respective chucks can control wafer alignment, temperature, pressure, rotation, alignment, flatness, and so forth. The (e.g., top) chuck can include an opening to receive a striker to cause the top wafer to couple with the lower wafer (e.g., at a wafer center point). The top wafer can deflect towards the lower wafer to couple thereto, and the coupling can thereafter extend radially outward based on the wafer-wafer forces, such as those described above. Thus, a propagation wave (also referred to as a lamination wave) can propagate outward from an initial coupling between the wafers.

In general, the propagation wave can be represented as a lateral wave which propagates incident to a vertical movement of the wafer. Vacuum pads (or other wafer holders) are generally disengaged prior to the propagation wave reaching them, to avoid interrupting the propagation of the propagation wave, or accumulations of stress related to large wavefront curvatures as the wave approaches the wafer holders. However, this disengagement can itself lead to the accumulation of stress, since without the coupled wafer holders, the wafer can move somewhat in advance of the wavefront (e.g., dynamic movement in response to the release or the advancement of the wavefront). Thus, the lamination can imprint any offsets as may contribute compressive or tensile stress in a bonded wafer.

According to the present disclosure, a portion of the wafer chuck (e.g., a portion configured to couple with a peripheral portion of a wafer) can maintain a coupling with the wafer during the propagation of the propagation wave to the entire wafer. Accordingly, the outer portion may be configured to move, at least in a vertical direction, relative to other portions of the chuck. For example, for a three-hundred-millimeter (mm) wafer, the vertical motion can include a displacement of less than one mm (e.g., about a half of a mm). The movable portion may further support lateral movement as may, in some cases, exceed the vertical motion. For example, the lateral motion can include a displacement of less than two mm (e.g., about one mm) for the three-hundred mm wafer.

The vertical motion can be provided according to a passive element of the wafer chuck. In some embodiments, the motion can be provided according to an elasticity of a material with differs from other portions of the chuck. For example, a first material of the chuck, as may be configured to provide a flat surface and avoid deflection, can include silicon carbide. A second material of the chuck, as may be configured to deform to promote the vertical motion, can include a polymer. The second material can include the wafer holders, or can separate the inner portion of the chuck from an outer portion including the wafer holders. Such an outer portion can include a same or similar material as the inner portion, among various further possibilities. In some embodiments, the motion can be provided according to an extension or recovery of a spring element. For example, a first and second portion of the chuck can both be made from silicon carbide and be coupled with one another by the spring element, such that the first and second portions can vertically offset from one another according to an extension of the spring element. A passive element, such as a spring or elastic material, can deform in response to the advancing wavefront, such that different circumferential portions of the passive element can deform at different times, in response to an asymmetric wavefront.

In some embodiments, multiple concentric portions of the wafer chuck can be configured to vertically move relative to one-another, to distribute the vertical displacement along the lateral surface, as may reduce a magnitude of the vertical motion between any adjoining portions. For example, multiple concentric rings of the spring elements or the second material can be provided. Further, in some embodiments, each of the concentric rings can include or otherwise correspond to (e.g., be disposed proximal to) a set of the wafer holders, such that the wafer holders can be actuated subsequent to the passage of the propagation wave.

One aspect of the present disclosure is directed to a method. The method includes engaging a wafer holder configured to selectively couple with a first wafer to couple the first wafer with a wafer chuck having a lateral surface, the wafer chuck including a first portion and a movable second portion that is displaceable in a vertical direction perpendicular to the lateral surface. The method includes instantiating, with the wafer holder engaged, wafer bonding between the first wafer and a second wafer. The method includes maintaining the engagement of the wafer holder while a propagation wave of the wafer bonding reaches the wafer holder to cause a vertical displacement of the second portion of the wafer chuck, relative to the first portion.

The method can further include disengaging the wafer holder subsequent to the propagation wave of the wafer bonding reaching the wafer holder to cause a recovery of the vertical displacement of the wafer holder.

The wafer holder can include a vacuum pad.

The second portion of the wafer chuck can be coupled with the first portion by a spring element configured to extend corresponding to the vertical displacement.

The method can include actuating an interlock of the spring element to prevent extension or recovery of the spring element, wherein the actuation is configured to adjust an accumulation of stress in the bonded first and second wafers.

The wafer chuck can include a first material along an inner portion of the lateral surface coupled with the first wafer and a second material configured to exhibit greater compliance for vertical deflection than the first material radially outward from, and coupled with, the inner portion; and an outer portion including the vacuum pad.

The outer portion and the inner portion can include the first material. The second material can be disposed between the inner portion and the outer portion.

The wafer chuck can include a first material along an inner portion of the lateral surface coupled with the first wafer. The wafer chuck can include a second material configured to exhibit greater compliance for vertical deflection than the first material radially outward from, and coupled with, the inner portion, wherein the vacuum pad extends through the second material.

The wafer chuck can include multiple movable portions arranged concentrically about one-another. The method can include disengaging the wafer holder at a first time. The method can include disengaging a second set of wafer holders at a second time, wherein an offset between the first time and the second time is configured to control an accumulation of stress in the first wafer and the second wafer.

The method can include detecting, via one or more propagation sensors, a position of the propagation wave; and determining the offset based on the position of the propagation wave.

Another aspect of the present disclosure is directed to a system for fabricating semiconductor devices. The system includes a first portion of a semiconductor chuck including a first material along a facing thereof. The system includes a second portion of the semiconductor chuck circumscribed about the first portion along the facing, the second portion including a second material configured to exhibit greater compliance to vertical deflection than the first material, wherein the second portion includes wafer holder disposed along the facing, the wafer holder configured to selectively couple with a semiconductor wafer along the facing.

The wafer holder can include a vacuum pad disposed within the second material.

The second portion can include the wafer holder disposed radially outward from the second material to couple with an edge of the semiconductor wafer, the second material configured to deflect vertically and couple the first portion with the second portion.

The system can include one or more processors to configured to cause a striker to displace a first semiconductor wafer from the facing to initiate a propagation wave. The one or more processors can cause an actuation of the wafer holder to decouple from the semiconductor wafer subsequent to an arrival of the propagation wave at the wafer holder.

The system can further include a sensor to detect the propagation wave, wherein the actuation of the wafer holder is responsive to a signal detected by the sensor.

The semiconductor chuck can include a plurality of concentric rings of the second material, each configured to vertically deflect the facing of the semiconductor chuck.

The first material can include silicon carbide (SiC), silicon dioxide (SiO2), silicon oxynitride (SiOXNY), silicon oxy-carbonitride (SiOCN), silicon carbonitride (SiCN), silicon nitride (SiN), alumina (Al2O3), or aluminum nitride (AlN). The second material can include polydimethylsiloxane (PDMS), polyether ether ketone (PEEK), polyimide (PI), polyether imide (PEI), polymethylmethacrylate (PMMA), polyamide (PA), polyamide imide (PAI), polybutylene terephthalate (PBTP), or liquid crystal polymers.

Another aspect of the present disclosure is directed to a wafer chuck. The wafer chuck includes an inner portion including a first material, and having an opening to receive a striker. The wafer chuck includes an outer portion including a vacuum pad, wherein the outer portion is configured to move vertically, relative to the inner portion while coupled with a semiconductor wafer.

The inner portion can couple with the outer portion by a second material, wherein substantially all of the vertical movement is based on an elasticity of the second material.

The inner portion can couple with the outer portion by a spring element, wherein substantially all of the vertical movement is based on an extension of the spring element.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Indeed, various features of the figures may be intentionally emphasized to depict various features thereof. Unless indicated as representing the background art, the figures represent aspects of the disclosure. For purposes of clarity, not every component may be labeled in every drawing. In the drawings:

FIG. 1 illustrates an exploded diagram of a system for wafer bonding, in accordance with some embodiments.

FIG. 2 illustrates a top view of a propagation wave generated by the system of FIG. 1, in accordance with some embodiments.

FIG. 3 illustrates a cross sectional view of the propagation wave of FIG. 2, in accordance with some embodiments.

FIG. 4 illustrates a cross sectional view of a displacement of the top chuck caused by the propagation wave of FIG. 2, in accordance with some embodiments.

FIG. 5 illustrates a cross sectional view of a recovery of the displacement of the top chuck depicted in FIG. 4, in accordance with some embodiments.

FIG. 6 illustrates a top view of a semiconductor chuck including a conformal portion laterally offset from vacuum pads, in accordance with some embodiments.

FIG. 7 illustrates a top view of a semiconductor chuck including multiple concentric conformal portions, in accordance with some embodiments.

FIG. 8 illustrates a top view of a semiconductor chuck including vacuum pads coupled with a central portion of the chuck according to a spring element, in accordance with some embodiments.

FIG. 9 illustrates a cross sectional view of the displacement of the semiconductor chuck of FIG. 8, in accordance with some embodiments.

FIG. 10 illustrates a block diagram illustrating a method of wafer bonding, in accordance with some embodiments.

FIG. 11 illustrates a block diagram illustrating an architecture for a computer system that can be employed to implement elements of the systems and methods described and illustrated herein.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. Although certain figures show various elements and operations related to wafer bonding systems to reduce a stress of a semiconductor wafer, other elements and operations are contemplated, and indeed, the techniques described herein may be implemented to achieve various stress profiles. Moreover, although references herein are made to “top,” “bottom,” “vertical,” “lateral” and the like, such descriptions are intended to describe one or more depicted embodiments, and not intended to provide limiting effect. For example, in some embodiments, the top chuck and bottom chuck, or individual features thereof, may be inverted, rotated, skewed, or so forth.

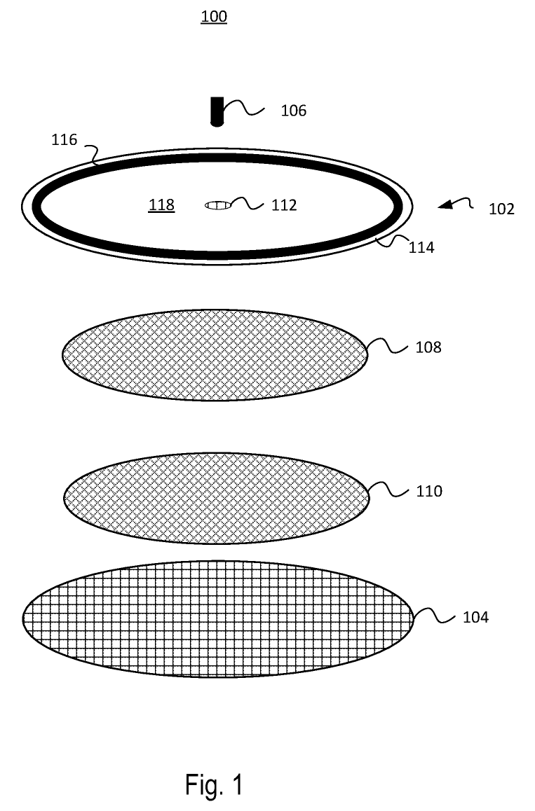

FIG. 1 illustrates an exploded diagram of a system 100 for wafer bonding, in accordance with some embodiments. The system 100 includes a top chuck 102 configured to interface with a bottom chuck 104. The top chuck 102 and bottom chuck 104 can perform various operations, such as temporary or permanent bonding of wafers such as the depicted top wafer 108 and bottom wafer 110. Thus, the top chuck 102 and bottom chuck 104 may be referred to as wafer chucks, semiconductor chucks, and the like, without limiting effect. According to various embodiments, the top wafer 108 and bottom wafer 110 can include semiconductor wafers at various stages of fabrication. For example, either wafer can include a silicon, silicon-germanium, or other intrinsic semiconductor wafer, a wafer with various circuits formed along an active surface thereof, a wafer with various metallization layers formed over such active circuits, or a carrier wafer configured to couple with such components.

The top chuck 102 can be operatively coupled with a striker 106 to couple a top wafer 108 with a bottom wafer 110, the top wafer 108 being operatively coupled with the top chuck 102 and the bottom wafer 110 being operatively coupled with the bottom chuck 104. According to various embodiments, the striker 106 can be replaced by various wafer coupling mechanisms, such as a thermal element or a lateral surface of the top chuck 102 or bottom chuck 104 configured to cause a coupling at a predefined point, such as a center of the wafers 108, 110 (e.g., can include a slight convexity to a surface).

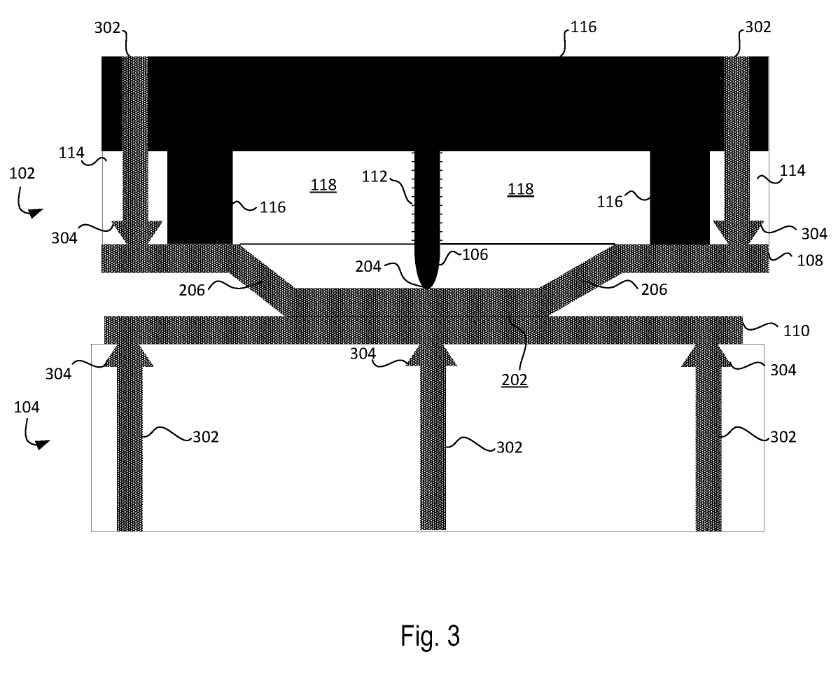

The top chuck 102 can include an outer portion 114 which includes a wafer holder such as an electro-static, mechanical, or vacuum-based holder, such as the vacuum pads 304 of FIG. 3. The outer portion 114 can circumscribe an inner portion 118 which can include further wafer holders (not depicted) of a same or different type as the outer portion 114. Any of the wafer holders described herein can be selectively engaged. For example, wafer holders of the inner portion 118 can be disengaged subsequent to the passage of the wavefront to aid the displacement of the top wafer 108 outwards towards the bottom wafer 110 upon a receipt, through an opening 112 of the top chuck 102, of the striker 106, or maintain engagement during the propagation of the wave.

A conformal portion 116 of the wafer chuck can intermediate the inner portion 118 from the outer portion 114. The conformal portion 116 can interface with the top wafer 108 and can deform with the top wafer 108 to reduce an amount of accumulated stress therein. For example, during bonding operations, the conformal portion 116 can deform, absorbing energy to reduce an accumulation of stress within the top wafer 108 to reduce or eliminate a compressive force incident to a propagation wave between the top wafer 108 and the bottom wafer 110. In some embodiments, the conformal portion 116 can be provided as the outer portion 114. For example, the wafer holders can extend through the conformal portion 116 to couple with the top wafer 108 (e.g., vacuum pads can be disposed along a surface of the conformal portion 116, as may be referred to as either of an outer portion or conformal portion 116). The conformal portion 116 can exhibit elasticity in at least a vertical direction, such that the outer portion 114 can vertically deflect from the inner portion incident to wave propagation (e.g., by about one mm). In some embodiments, the conformal portion 116 can exhibit elasticity in a lateral direction, such that stress accumulated by an outward transit of a propagation wave can be mitigated (e.g., by about two mm). The vertical or lateral deflection can be controlled according to a geometry, crystal orientation, or other aspect of the conformal portion 116, perpendicular to the lateral surface.

The inner portion 118, conformal portion 116, and outer portion 114 can include various materials. For example, in some embodiments, the inner portion 118 or outer portion 114 can be or include silicon carbide (SiC), silicon dioxide (SiO₂), silicon oxynitride (SiO_{X}N_{Y}), silicon oxy-carbonitride (SiOCN), silicon carbonitride (SiCN), silicon nitride (SiN), alumina (Al₂O₃), or aluminum nitride (AlN). The conformal portion 116 can be or include polydimethylsiloxane (PDMS), polyether ether ketone (PEEK), polyimide (PI), polyether imide (PEI), polymethylmethacrylate (PMMA), polyamide (PA), polyamide imide (PAI), polybutylene terephthalate (PBTP), or liquid crystal polymers. The liquid crystal polymers can include additives such as such as glass or carbon fibers, to modulate their compliance.

In some embodiments, the conformal portion 116 can be substituted for another component to vertically deflect portions of the top chuck 102. For example, the conformal portion 116 can be substituted for a spring element coupling the inner portion 118 with the outer portion 114. In some embodiments, multiple conformal portions 116, spring elements, or other components to vertically deflect portions of the top chuck can be provided radially inward/outward from one another. Although such a chuck might increase a number of vertical transitions, a magnitude of the transitions would be distributed along various radial positions, as may reduce maximum or average stress. The various concentric rings can be associated with different force-displacement curves relative to one another, to control a stress profile of the bonded first and second wafers. For example, a material or radial thickness of the conformal portions 116 or a spring force of the spring element can vary between the radial positions. Moreover, some features of the top chuck 102 and the bottom chuck 104 can be exchanged with one another. For example, the opening 112 to receive the striker 106 or conformal portion 116 to move vertically, can be provided on the bottom chuck 104.

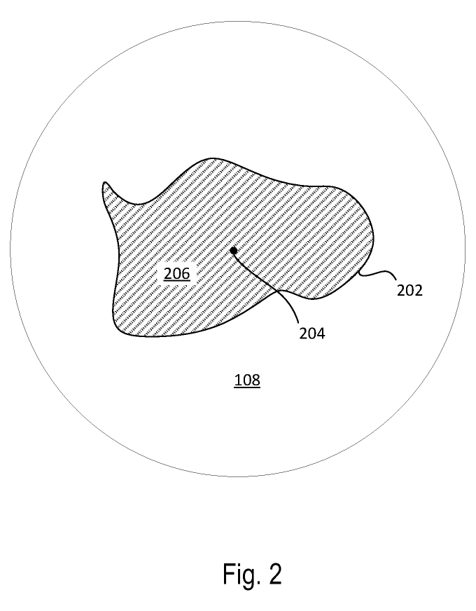

FIG. 2 illustrates a top view of a propagation wave 202 generated by the system 100 of FIG. 1, in accordance with some embodiments. The propagation wave 202 refers to a lateral boundary of an interface between the top wafer 108 and bottom wafer 110 (not depicted). For example, upon the striker 106 deflecting the top wafer 108 towards the bottom wafer 110, the top wafer 108 can couple to the bottom wafer 110 at an instantiation point 204 thereof (e.g., a center of the wafers 108, 110 where the striker 106 is centrally located relative to the wafers 108, 110). The lateral location at the center of the top wafer 108 and bottom wafer 110 or other location which initiates the inter-wafer lamination (e.g., corresponding to the striker 106) may be referred to as an instantiation point. The propagation wave 202 can extend generally radially outward, such that the propagation wave 202 defines a lateral boundary a coupled portion 206 of the top wafer 108 and bottom wafer 110, and a portion of each of the top wafer 108 and bottom wafer 110 which are not coupled. The propagation wave 202 may also be referred to as a lamination wave, where the propagation refers to a lamination formed from the combination of the top wafer 108 and bottom wafer 110.

In some embodiments, the propagation wave 202 can propagate at a similar rate in each direction, such that the propagation wave 202 can be substantially concentric to the outer edge of the circular wafers 108, 110. In some embodiments, as depicted, the propagation wave 202 may propagate at different rates in different lateral directions based on non-uniform pressure or temperature variations, thickness variations, or so forth. That is, the propagation wave 202 can travel at different effective speeds towards the outer edge of the, for example, top wafer 108. Where a radial extremity of the top wafer 108 is coupled, via a wafer holder such as a vacuum pad 304, to the outer portion 114 of the top chuck 102 (not depicted), the propagation wave 202 may arrive at each of the segments of the outer portion 114 at a different time. Thus, as is described herein, each wafer holder or various combinations thereof can be operated responsive to a detection of the propagation wave 202. Further, the inclusion of a conformal portion 116 of a wafer holder can deform along with a top wafer 108, or absorb energy associated with the propagation wave 202 from the wafers 108, 110 as is further described herein. In some embodiments, a passive component, such as a spring or conformal portion 116 of a chuck (or the outer portion generally) can include radial segments to reduce a transference of a vertical or horizontal deflection between the circumference of the chuck, to further reduce stress accumulations in a bonded wafer.

FIG. 3 illustrates a cross sectional view of the propagation wave 202 of FIG. 2, in accordance with some embodiments. Further included in the view are the top chuck 102 and the bottom chuck 104 vertically bounding the top wafer 108 and bottom wafer 110. The bottom chuck 104 is coupled with the bottom wafer 110 by various vacuum pads 304 coupled to vacuum lines 302 extending through the bottom chuck 104. The various vacuum lines 302 may be individually actuated, or collectively controlled (e.g., so that all or a portion of lines are engaged together). The vacuum pads 304 are shown at lateral extremes of the bottom chuck 104, vertically corresponding to the segments of the outer portion 114 of the top chuck 102, as well as to portions of the bottom chuck 104 vertically corresponding to the inner portion 118 of the top chuck 102. Vacuum pads 304 are further depicted as coupled with vacuum lines 302 extending through the outer portion 114 of the top chuck 102. For example, the vacuum pads 304 and vacuum lines 302 can extend at regular spacing around a periphery of the top chuck 102. Although not depicted for clarity, the inner portion 118 of the top chuck 102 can include vacuum pads 304. Further, in various embodiments, various other wafer holders can be substituted for any of the vacuum pads 304 described with regard to the various illustrative examples herein.

The striker 106 is shown in an engaged state, extending through the opening 112 of the top chuck 102 causing the downward deflection of the top wafer 108 to couple to the bottom wafer 110. Such deflection can be provided as less than one mm. Absent a vertical displacement of the outer portion 114 of the top chuck 102, the wavefront can lead to large accumulations of stress as the wavefront approaches the wafer holders at the edge of the top wafer 108, since the wafer holder would prevent the top wafer 108 from releasing from the wafer holder to couple with the bottom wafer 110. Consequently, accumulated stress or misalignment of features between the top wafer 108 and bottom wafer 110 may impact a performance, reliability, or yield of various semiconductor devices. By inclusion of the conformal portion 116, such compression or accumulation of compressive stresses may be reduced or eliminated. For example, the conformal material can expand vertically upon an arrival of the propagation wave 202, to cause a downward displacement of the outer portion so as to reduce the amount of stress accumulated in the top wafer 108. The conformal portion 116 can further conform to the wavefront 202 in a lateral direction, as can reduce compressive stress imprinted into the bonded wafer (from the outward propagation of the wavefront).

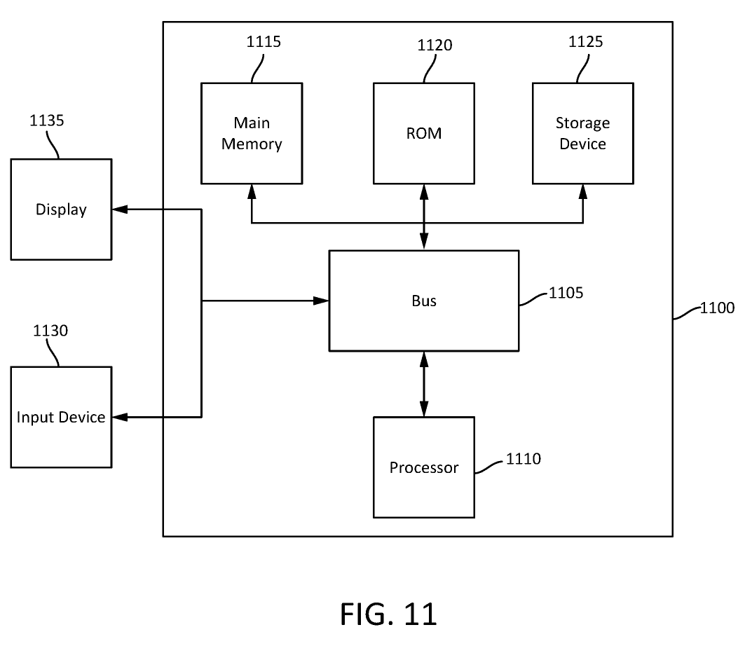

The depicted figure can exclude some portions of the top chuck 102 or various elements interfacing therewith. Further, some portions may not be depicted in the figure. For example, the figure excludes one or more interconnections between the various vacuum lines 302 or an operative connection between the vacuum lines 302 and any valve, regulator, pump, controller, or the like. Further, sensors configured to detect a signal indicative of a speed or position of the propagation wave 202, can be disposed along a face of the top chuck 102 (or bottom chuck 104, as discussed with regard to the substitution of features in the description of FIG. 1). According to the depicted example, the conformal portion is provided as a passive material configured to deflect in at least a vertical direction. However, any components of the present disclosure, or further components still, may be connected to one or more processors, coupled to memory, configured to actuate, monitor, or otherwise control the various components. For example, the processor (which may also be referred to as a controller, without limiting effect), can be or include the processor 1110 of FIG. 11.

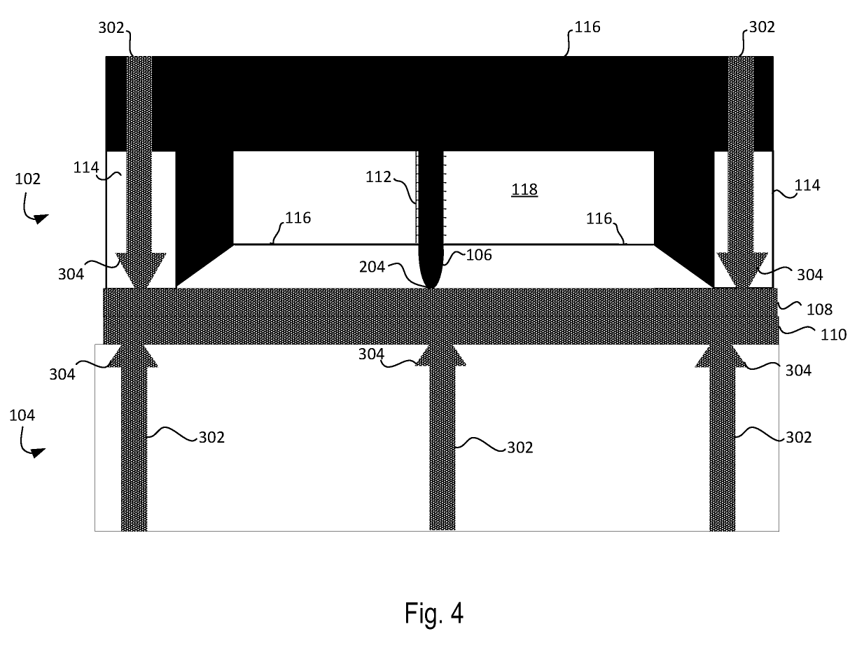

FIG. 4 illustrates a cross sectional view of a displacement of the top chuck caused by the propagation wave 202 of FIG. 2, in accordance with some embodiments. As is depicted, the wafer holders (e.g., the vacuum pads 304) maintain a coupling with the top wafer 108 during a vertical deflection of the top wafer 108 to couple with the bottom wafer 110. That is, the outer portion 114 of the top chuck 102 deflects vertically, relative to the inner portion 118. The material or geometry of the conformal material can be configured to maintain a coupling between the wafer holder and the top wafer during the bonding. For example, a flexural modulus of the conformal material, in combination with a geometry can be selected to correspond to a vertical displacement of the top wafer 108 during bonding. Extending a lateral dimension of the conformal material can (for a material having a given flexural modulus) lower a resistance to vertical deflection. Similarly, extending a vertical height of the conformal material can lower the resistance to vertical deflection (since the conformal material expansion is lowered on a proportional basis of the total height).

The stress/strain relationship of the conformal material can further be adjusted according to various non-uniform shapes, or an interface between the conformal material and the outer portion 114 or inner portion 118 of the top chuck 102, as may control an elastic force applied between the outer portion 114 and inner portion 118. Such a force can, in turn, control a stress imprinted into the bonded wafers and a rate of deflection of the outer portion 114 (and the propagation wave 202). Moreover, in some embodiments, the outer portion 114 can be the conformal portion 116, as may simplify construction. For example, the vacuum pads 304 and vacuum lines 302 can extend through the conformal material of the conformal portion 116, such that the deflection of the conformal portion 116 can extend from an inner surface to a junction between vacuum pads 304 and the top wafer 108.

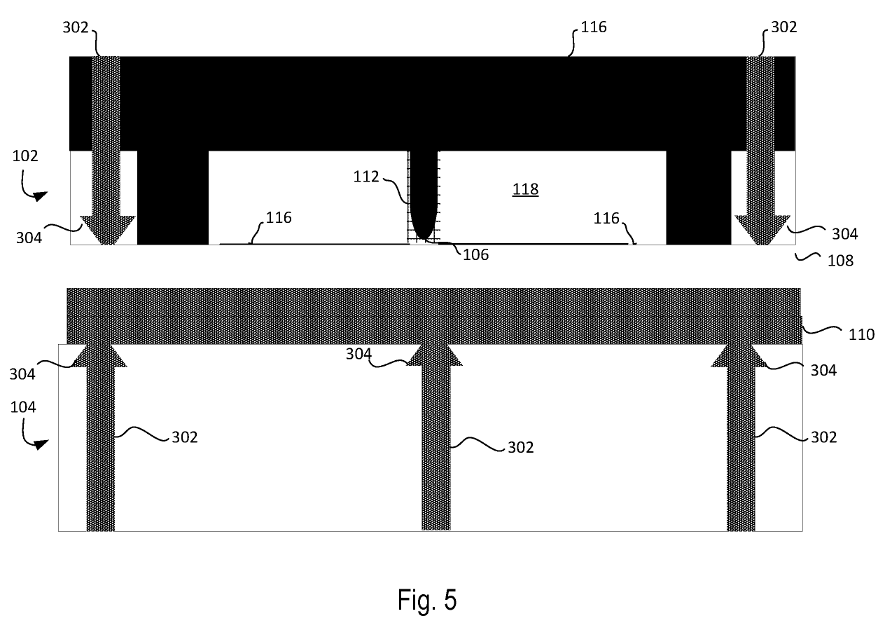

FIG. 5 illustrates a cross sectional view of a recovery of the displacement of the top chuck 102 depicted in FIG. 4, in accordance with some embodiments. The striker 106 is depicted in a retracted position, as can correspond to its withdrawal prior or subsequent to the propagation wave 202 reaching a periphery of the top wafer 108 and the bottom wafer 110 to bond the top wafer 108 with the bottom wafer 110. The recovery of the displacement of the top chuck 102 can follow a disengagement of the wafer holders, as commanded by a controller. For example, the controller can be configured to release the wafer holders based on a predetermined temporal offset or a detection of the propagation wave 202 at one or more propagation sensors.

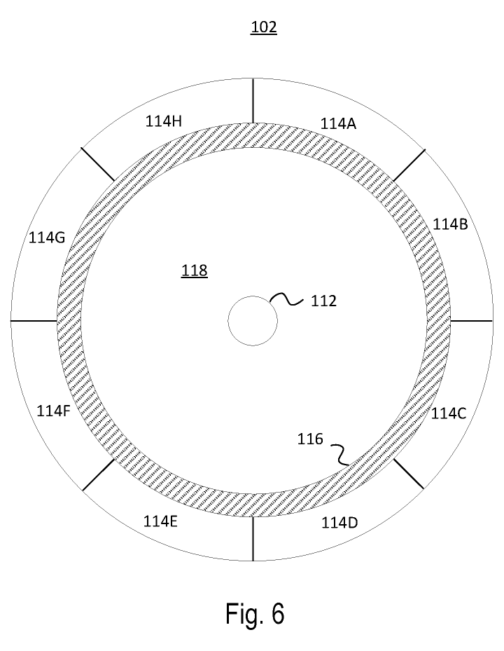

FIG. 6 illustrates a top view of a facing of a semiconductor chuck, in accordance with some embodiments. For example, the chuck can be a top chuck 102, wherein the facing is configured to interface with a top wafer 108 (e.g., the top chuck 102 of FIGS. 3-5). The outer portion 114 is provided as various radial segments (segments 114A-114H, referred to collectively as outer portion 114) configured to deflect (at least vertically) differently from one another, as may thus conform to any asymmetries in the propagation wave 202. In some embodiments, the conformal portion 116 can be radially segmented to reduce forces transferred between the various segments of the conformal portion 116 (or between the inner portion 118 and the outer portion 114) through the conformal portion 116.

The segmentation of the conformal portion 116 can reduce a mechanical coupling between the various segments such that different segments of the conformal portion 116 can displace laterally in different directions or at different times, relative to a continuous conformal portion 116, wherein forces internal to the conformal portion 116 can limit a displacement in one or more directions. That is, in some embodiments, the conformal portion 116 can exhibit conformance in a lateral direction as well as the vertical direction. Where a propagation wave 202 interfaces with the conformal portion 116 at a first location, a nearby location of the conformal portion 116 can, due to adhesive forces within the conformal portion 116, cause a deformation of the wafer prior to an arrival of the propagation wave 202. Conversely, where a propagation wave 202 radiates outward generally concentrically, the segmentation of the conformal portion 116 may operate more similarly to a continuous conformal portion 116, according to some embodiments. The segments of the conformal portion 116, collectively, can be referred to as circumscribing the inner portion 118. Likewise, the outer portion 114 circumscribes the inner portion 118 and the conformal portion 116. Such circumscription may include gaps such as the depicted gaps between the segments of the conformal portion 116, or the conformal portion 116 can include various other geometries.

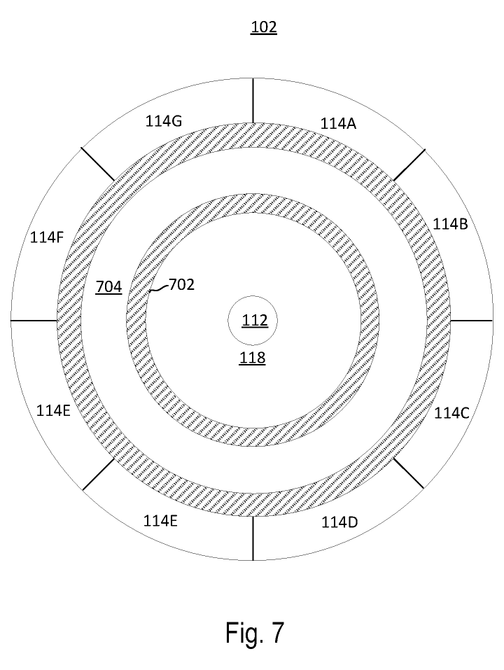

FIG. 7 illustrates a top view of a facing of another semiconductor chuck, in accordance with some embodiments. As described with regard to FIG. 6, the chuck can be a top chuck 102, wherein the facing is configured to interface with a top wafer 108. As is depicted, a further conformal portion 702 defines a further non-conformal portion 704. For example, the further non-conformal portion 704 can be configured to maintain a wafer flatness and can, like other portions of the wafer, include wafer holders, heaters, propagation (or other) sensors, and so on. The conformal portion 116 and the further conformal portion 702 can be provided with different geometries (or materials) to control at least a vertical deflection. For example, one of the conformal portion 116 or the further conformal portion 702 can be provided with radial thicknesses varying from one-another, as based on different forces or stress targets associated with the different portions of the wafers. In some embodiments, any of the inner portion 118, outer portion 114, or further non-conformal portion 704 can include vacuum pads 304 or other wafer holders. Such wafer holders can be separately or commonly activatable. The wafer holders can be disengaged after the propagation wave 202 passes them. For example, all wafer holders can be commonly disengaged after a completion of a bonding between the wafer, or some wafer holders can be actuated subsequent to the propagation wave 202 passing over them, but before the propagation wave 202 reaches other wafer holders. The wafer holders can be (commonly or individually) disengaged based on a detection of the propagation wave 202 or according to predefined times for expected propagation of the propagation wave 202.

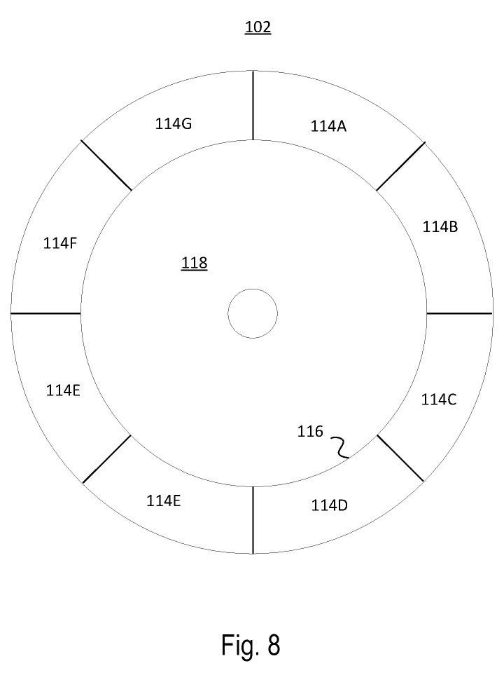

FIG. 8 illustrates a top view of a semiconductor chuck including vacuum pads coupled with a central portion 118 of the chuck according to a spring element, in accordance with some embodiments. As described with regard to FIGS. 6-7, the chuck can be a top chuck 102, wherein the facing is configured to interface with a top wafer 108. At least a portion of the vacuum pads can be positioned within an outer portion 114. The outer portion 114 can include one or more segments, as described above with regard to the segments of FIG. 6. In some embodiments, the outer portion 114 can include a single annular ring that circumscribes the inner portion 118. Each of the one or more segments can couple with the inner portion 118 via at least one spring element. In some embodiments, multiple segments can further couple with one-another via spring elements. According to an extension or retraction of the spring elements, the various segments of the outer portion 114 can deflect vertically from the inner portion 118. Accordingly, as for the conformal portion 116, the spring element can aid a propagation wave 202 to bond a pair of wafers while maintaining contact with a wafer holder (e.g., for both wafers). That is, a vertical displacement of the outer portion 114 from the inner portion 118 can equal a vertical displacement of a wafer pair during wafer bonding.

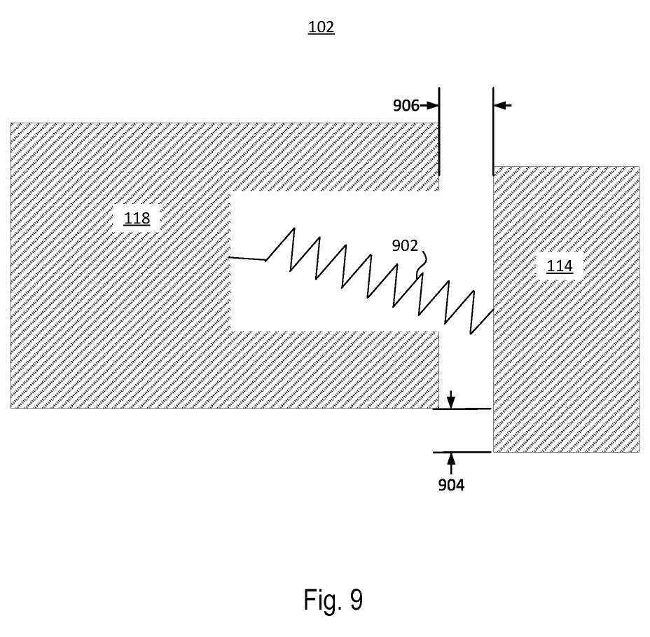

FIG. 9 illustrates a cross sectional view of the displacement of the semiconductor chuck of FIG. 8, in accordance with some embodiments. The cross-sectional view depicts a peripheral edge of the chuck, including a junction between an inner portion 118 and outer portion 114. The junction may be provided generally symmetrically around the outer edge of the inner portion 118 and an inner edge of the outer portion 114, as can include one or more segments. At least the outer portion 114 can include vacuum pads 304 or other wafer holders to couple with a wafer. A spring element 902 couples the inner portion 118 with the outer portion 114. The spring element 902 can include a circumferential spring extending around a perimeter of the inner portion 118, or other springs spaced from one another at regular interval around the perimeter. For example, the spring element can include a micro-electro-mechanical system (MEMS) device. The spring can be embedded in a side channel of at least one of the inner portion 118 or the outer portion 114, or can couple the inner portion 118 with the outer portion 114 along an upper surface, opposite from a facing for a wafer.

Various further types and mounting geometries of spring elements 902 can be substituted for the illustrative examples provided herein. In some embodiments, a spring element 902 can be provided with a limited range of motion (e.g., only or primarily in a vertical direction 904). For example, such a spring element 902 can be used in an embodiment lacking lateral conformance, or in combination with another lateral conformance strategy (e.g., a conformal portion 116). In some embodiments, separate spring elements 902 can be provided for movement in the vertical direction 904 and lateral direction 906. In some embodiments, a spring element 902 can include or couple with an interlock to prevent extension (or relaxation) of the spring element 902, as can avoid undesired deflection between the inner portion 118 and outer portion 114 of the chuck (or further portions in embodiments including further portions). For example, the controller can actuate the interlock to permit movement of the spring element 902 while the wavefront advances over a wafer holder coupled with a wafer, but inhibit such movement at other times, to maintain wafer flatness. Such actuation can be based on a predefined time for an expected arrival of the wavefront (e.g., relative to the striker actuation), or based on a detection of the propagation wave 202.

When a vertical force is applied to the outer portion relative to the inner portion (e.g., by the propagation of the wavefront incident to bonding of a pair of wafers), the outer portion 114 can vertically deflect, relative to the inner portion 118. For example, a vertical deflection distance 904 can correspond to a vertical movement of an upper wafer 108 during a bonding process. In some embodiments, the spring element 902 can also be configured to provide lateral expansion, such as according to the depicted lateral distance 906. Such lateral displacement can reduce stress accumulation from lateral motion (e.g., the wavefront propagation). In some embodiments, an interface material can be provided at a junction of the inner portion 118 and the outer portion 114. In some embodiments, multiple concentric rings of spring elements 902 can be provided, as for the conformal material depicted in FIG. 7. Accordingly, multiple movable portions can be provided arranged concentrically about one-another. Moreover, various combinations of spring elements 902 and conformal portions 116 can be provided for a top chuck 102 or bottom chuck 104.

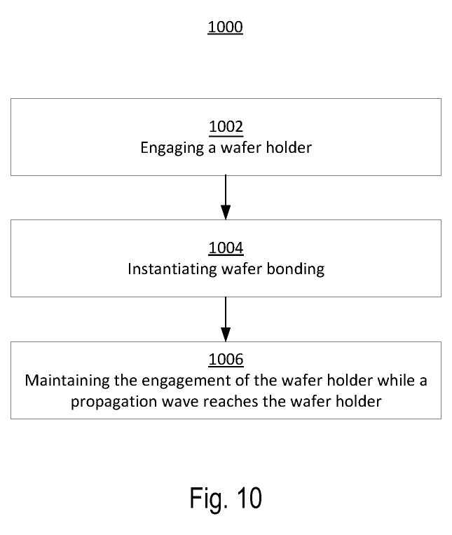

FIG. 10 illustrates a method 1000 of wafer bonding, in accordance with some embodiments. In brief summary, the method 1000 includes engaging wafer holders to couple a wafer chuck with a first wafer at operation 1002. The method 1000 includes instantiating wafer bonding at operation 1004 (e.g., by actuating a striker 106). The method 1000 includes maintaining the engagement of the wafer holder while a propagation wave 202 of the wafer bonding reaches the wafer holder at operation 1006 (e.g., until the propagation wave 202 reaches the periphery of the wafer around an entire circumference of the wafer, to complete the bonding). It is noted that the method 1000 is merely an example and is not intended to limit the present disclosure. Accordingly, it is understood that additional operations may be provided before, during, and after the method 1000 of FIG. 10. For example, in some embodiments, the various wafer holders may be actuated responsive to a detection of a propagation wave 202 incident to the instantiation of wafer bonding, or the wafer holders can be actuated to decouple from the wafer, based on the detection of the propagation wave 202, or an elapsed time from the instantiation of the wafer bonding.

Referring again to operation 1002, at least one wafer holder is actuated to couple a first wafer to a lateral surface of a wafer chuck. The wafer chuck can include an inner portion 118 which is remains vertically stable relative to a vertical movement of a movable second portion (e.g., outer portion 114). The wafer holder can be implemented as a vacuum pad, such as a vacuum ring on an outer portion 114 of the wafer chuck, or as a series of vacuum pads spaced around the outer portion 114 of the wafer chuck. The wafer chuck can be a top wafer chuck 102, and the wafer can be a top wafer 108 configured to bond with a bottom wafer 110 coupled to a bottom wafer chuck 104. The actuation can include a processor causing one or more valves, pumps, or the like to interface with a vacuum pad 304 to couple the wafer 108 to the chuck 102. The coupling can be configured to prevent a horizontal or vertical displacement of the wafer or can permit some lateral forces to displace the wafer 108.

The first and second portion can couple with one-another via various deformable elements. For example, a conformal material or a spring element 902 can be configured to extend, corresponding to the vertical displacement. In some embodiments, the deformation of the deformable material can be actuated, such as via an actuation of an interlock to prevent extension or recovery of the spring element. The actuation can adjust an accumulation of stress in the bonded first and second wafers. For example, deformation can be initially prevented to maintain or measure wafer flatness, but can be actuated to aid vertical deformation prior to an arrival of a propagation wave 202 at the deformable element.

The material of the various portions can be provided as a same material, and can further be provided as a first material interfacing with a second material, the second material configured to exhibit greater compliance for vertical deflection than the first material. An inner portion 118 of the facing can include the first material with the second material disposed radially outward. An outer portion 114 can be disposed radially outward from the inner portion 118. The outer portion 114 can include wafer holders such as vacuum pads 304. In some embodiments, the outer portion 114 can be the (compliant) second material. The vacuum pads 304 can extend through the second material. For example, an outer portion 114 of the first material can be omitted.

Referring again to operation 1004, wafer bonding is instantiated. The instantiation can be by an operation of a striker 106, or a pressure, temperate or the like exercised by the top wafer chuck 102 or bottom wafer chuck 104 with respect to the top wafer 108 and bottom wafer 110. The instantiation can begin at a portion of the respective wafers 108, 110 laterally aligned with a first, inner portion 118 of the top wafer chuck 102, which is or includes a first material which is generally non-conformal (e.g., less conformal than the second portion). A second portion can intermediate the first portion, such that the second portion can vertically conform to a propagation wave 202. In some embodiments, the propagation wave 202 can propagate over further concentric portions, such as further portions of or including the first material, and intermediating conformal portions 116. The propagation wave 202 can interact with the conformal portions 116 or the spring element 902 (e.g., impart stress thereupon to cause a vertical deflection of portions of a facing of the chuck). The energy imparted to the conformal material can reduce a residual stress of the bonded wafer assembly formed according to the method 1000.

Referring again to operation 1006, engagement of the wafer holders is maintained while the propagation wave of the wafer bonding reaches the wafer holder to cause a vertical displacement of the second portion of the wafer chuck, relative to the first portion. The wafer holders can displace along with the facing of the wafer chuck.

In some embodiments, method 1000 can further include disengaging the wafer holder. For example, the wafer holder can be disengaged subsequent to the propagation wave of the wafer bonding reaching the wafer holder. The disengagement can cause a recovery of the vertical displacement of the wafer holder. The disengagement can be timed based on a detected position of, or predetermined time for the propagation of a propagation wave 202. In some embodiments, various wafer holders can be disengaged at different times. For example, a first set of wafer holders can be disengaged at a first time, and the second set of wafer holders can be disengaged at a second time. An offset between the first time and the second time can be controlled or adjusted to control an accumulation of stress in the first wafer and the second wafer. For example, the offset can be determined based on a position of a detected propagation wave 202 or a predetermined time for the propagation of the propagation wave 202. The second set of wafer holders can be disposed radially outward from the first set of wafer holders.

FIG. 11 illustrates a block diagram illustrating an architecture for a computer system that can be employed to implement elements of the systems and methods described and illustrated herein. The computer system or computing device 1100 can include or be used to implement a controller or its components, and components thereof, which can interface with a top chuck 102 or other component of the systems 100 and methods described herein. The computing system 1100 includes at least one bus 1105 or other communication component for communicating information and at least one processor 1110 or processing circuit coupled to the bus 1105 for processing information. The computing system 1100 can also include one or more processors 1110 or processing circuits coupled to the bus for processing information. The computing system 1100 also includes at least one main memory 1115, such as a random access memory (RAM) or other dynamic storage device, coupled to the bus 1105 for storing information, and instructions to be executed by the processor 1110. The main memory 1115 can be used for storing information during execution of instructions by the processor 1110. The computing system 1100 may further include at least one read only memory (ROM) 1120 or other static storage device coupled to the bus 1105 for storing static information and instructions for the processor 1110. A storage device 1125, such as a solid state device, magnetic disk or optical disk, can be coupled to the bus 1105 to persistently store information and instructions.

The computing system 1100 may be coupled via the bus 1105 to a display 1135, such as a liquid crystal display, or active matrix display. An input device 1130, such as a keyboard or mouse may be coupled to the bus 1105 for communicating information and commands to the processor 1110. The input device 1130 can include a touch screen display 1135.

The processes, systems and methods described herein can be implemented by the computing system 1100 in response to the processor 1110 executing an arrangement of instructions contained in main memory 1115. Such instructions can be read into main memory 1115 from another computer-readable medium, such as the storage device 1125. Execution of the arrangement of instructions contained in main memory 1115 causes the computing system 1100 to perform the illustrative processes described herein. One or more processors in a multi-processing arrangement may also be employed to execute the instructions contained in main memory 1115. Hard-wired circuitry can be used in place of, or in combination with, software instructions together with the systems and methods described herein. Systems and methods described herein are not limited to any specific combination of hardware circuitry and software.

Although an example computing system has been described in FIG. 11, the subject matter including the operations described in this specification can be implemented in other types of digital electronic circuitry, or in computer software, firmware, or hardware, including the structures disclosed in this specification and their structural equivalents, or in combinations of one or more of them.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
engaging a wafer holder configured to selectively couple with a first wafer to couple the first wafer with a wafer chuck having a lateral surface, the wafer chuck comprising a first portion and a movable second portion that is displaceable in a vertical direction perpendicular to the lateral surface;
instantiating, with the wafer holder engaged, wafer bonding between the first wafer and a second wafer; and
maintaining the engagement of the wafer holder while a propagation wave of the wafer bonding reaches the wafer holder to cause a vertical displacement of the second portion of the wafer chuck, relative to the first portion.

2. The method of claim 1, further comprising:
disengaging the wafer holder subsequent to the propagation wave of the wafer bonding reaching the wafer holder to cause a recovery of the vertical displacement of the wafer holder.

3. The method of claim 1, wherein the wafer holder comprises a vacuum pad.

4. The method of claim 3, wherein the second portion of the wafer chuck is coupled with the first portion by a spring element configured to extend corresponding to the vertical displacement.

5. The method of claim 4, further comprising:
actuating an interlock of the spring element to prevent extension or recovery of the spring element, wherein the actuation is configured to adjust an accumulation of stress in the bonded first and second wafers.

6. The method of claim 3, wherein the wafer chuck comprises:
a first material along an inner portion of the lateral surface coupled with the first wafer;
a second material configured to exhibit greater compliance for vertical deflection than the first material radially outward from, and coupled with, the inner portion; and
an outer portion including the vacuum pad.

7. The method of claim 6, wherein the outer portion and the inner portion comprise the first material and the second material is disposed between the inner portion and the outer portion.

8. The method of claim 3, wherein the wafer chuck comprises:
a first material along an inner portion of the lateral surface coupled with the first wafer; and
a second material configured to exhibit greater compliance for vertical deflection than the first material radially outward from, and coupled with, the inner portion, wherein the vacuum pad extends through the second material.

9. The method of claim 1, wherein the wafer chuck comprises multiple movable portions arranged concentrically about one-another, and further comprising:
disengaging the wafer holder at a first time; and
disengaging a second set of wafer holders at a second time, wherein an offset between the first time and the second time is configured to control an accumulation of stress in the first wafer and the second wafer.

10. The method of claim 9, further comprising:
detecting, via one or more propagation sensors, a position of the propagation wave; and
determining the offset based on the position of the propagation wave.

11. A system for fabricating semiconductor devices, comprising:
a first portion of a semiconductor chuck comprising a first material along a facing thereof; and
a second portion of the semiconductor chuck circumscribed about the first portion along the facing, the second portion comprising a second material configured to exhibit greater compliance to vertical deflection than the first material, wherein the second portion comprises wafer holder disposed along the facing, the wafer holder configured to selectively couple with a semiconductor wafer along the facing.

12. The system of claim 11, wherein the wafer holder comprises a vacuum pad disposed within the second material.

13. The system of claim 11, wherein the second portion comprises:
the wafer holder disposed radially outward from the second material to couple with an edge of the semiconductor wafer, the second material configured to deflect vertically and couple the first portion with the second portion.

14. The system of claim 11, further comprising one or more processors to configured to:
cause a striker to displace a first semiconductor wafer from the facing to initiate a propagation wave; and
cause an actuation of the wafer holder to decouple from the semiconductor wafer subsequent to an arrival of the propagation wave at the wafer holder.

15. The system of claim 14, wherein the system further comprises:
a sensor to detect the propagation wave, wherein the actuation of the wafer holder is responsive to a signal detected by the sensor.

16. The system of claim 11, wherein the semiconductor chuck comprises:
a plurality of concentric rings of the second material, each configured to vertically deflect the facing of the semiconductor chuck.

17. The system of claim 11, wherein:
the first material comprises silicon carbide (SiC), silicon dioxide (SiO₂), silicon oxynitride (SiO_{X}N_{Y}), silicon oxy-carbonitride (SiOCN), silicon carbonitride (SiCN), silicon nitride (SiN), alumina (Al₂O₃), or aluminum nitride (AlN); and
the second material comprises polydimethylsiloxane (PDMS), polyether ether ketone (PEEK), polyimide (PI), polyether imide (PEI), polymethylmethacrylate (PMMA), polyamide (PA), polyamide imide (PAI), polybutylene terephthalate (PBTP), or liquid crystal polymers.

18. A wafer chuck comprising:
an inner portion comprising a first material, and having an opening to receive a striker; and
an outer portion comprising a vacuum pad, wherein the outer portion is configured to move vertically, relative to the inner portion while coupled with a semiconductor wafer.

19. The wafer chuck of claim 18, wherein:
the inner portion is coupled with the outer portion by a second material, wherein substantially all of the vertical movement is based on an elasticity of the second material.

20. The wafer chuck of claim 18, wherein:
the inner portion is coupled with the outer portion by a spring element, wherein substantially all of the vertical movement is based on an extension of the spring element.
